(19) United States
(12) Patent Application Publication
(10) Pub. No.: US 2025/0378979 A1
(43) Pub. Date: Dec. 11, 2025

(54) CIRCUIT FOR CONTROLLING A CURRENT FLOW THROUGH A RELAY COIL FIELD

(71) Applicant: WAGO Verwaltungsgesellschaft mit beschränkter Haftung, Minden (DE)

(72) Inventors: Christian VOSS, Minden (DE); Torsten MEYER, Penningsehl (DE)

(73) Assignee: WAGO Verwaltungsgesellschaft mit beschränkter Haftung, Minden (DE)

(21) Appl. No.: 19/229,710

(22) Filed: Jun. 5, 2025

(30) Foreign Application Priority Data
Jun. 5, 2024 (DE) 10 2024 115 732.1

(51) Int. Cl. H01F 7/06; H03K 5/24

(52) U.S. Cl. CPC H01F 7/064; H03K 5/24

(57) ABSTRACT

A circuit for controlling a current flow through a relay coil with an electronic switch which controls the current flow through the relay coil and a comparator which controls a control voltage applied to a control input of the electronic switch. A first voltage is applied to a first input of the comparator, a second voltage derived from the current flow through the relay coil is applied to a second input of the comparator. The circuit is configured, after a switching operation caused by a switching current through the relay coil, to reduce the current flow through the relay coil to a holding current.

This nonprovisional application claims priority under 35 U.S.C. § 119 (a) to German Patent Application No. 10 2024 115 732.1, which was filed in Germany on Jun. 5, 2024, and which is herein incorporated by reference.

### BACKGROUND OF THE INVENTION

### Field of the Invention

The present invention relates to a circuit for controlling a current flow through a relay coil. In particular, the present invention relates to a circuit for reducing the holding current.

### Description of the Background Art

By changing the magnitude of the current flow through a relay coil, a magnetic field can be generated which causes two electrical conductors to connect or disconnect.

### SUMMARY OF THE INVENTION

A circuit according to the invention for controlling a current flow through a relay coil comprises an electronic switch which controls the current flow through the relay coil, and a comparator which controls a control voltage applied to a control input of the electronic switch, wherein a first voltage is applied to a first input of the comparator and a second voltage derived from the current flow through the relay coil is applied to a second input of the comparator. A circuit according to the invention is further configured to reduce the current flow through the relay coil to a holding current after a switching operation which is caused by a switching current through the relay coil.

In this regard, the term “circuit”, can refer to a combination of electrical and/or electronic components forming a functional arrangement. Furthermore, the term “comparator”, can refer to an electronic component which detects two input voltages and outputs an output voltage whose level changes when the sign of the difference between the input voltages changes. For example, the output voltage may be UA1 if the first input voltage is greater than the second input voltage and UA2 if the second input voltage is greater than the first input voltage.

Furthermore, the term “relay coil”, can refer to a coil of a relay which is configured to generate a magnetic field which causes a movement of a mechanical component from a first position (e.g. a resting position which is assumed when no current flows through the coil) to a second position (e.g. a holding position) through which an electrical circuit is closed or opened. The holding position may be a position in which the component is pushed (against a restoring force) against a mechanical stop by the magnetic field. The restoring force may be dimensioned such that when the relay coil is de-energized, the component returns to the resting position due to the restoring force, through which, for example, the circuit may be opened.

In this regard, the term “holding current”, can refer to a current which is sufficient to generate a magnetic field which holds the component in the holding position (against the restoring force). Furthermore, the term “switching current” can refer to a current which is sufficient to generate a magnetic field that forces the component to move from the resting position to the holding position (against the restoring force and the static friction occurring in the resting position), wherein the “switching current” is greater in magnitude than the “holding current”.

The comparator may be part of a switching regulator that is configured to (co-)use the relay coil as a magnetic energy storage device instead of a (separate) storage choke. A constant current source may be realized with the switching regulator, which allows the relay coil to be driven with a constant current and thus to maintain the magnetic field and the holding force independent of the operating temperature and the operating voltage of the circuit. For example, the current setpoint may be set via a reference voltage applied to the comparator, wherein the reference voltage is influenced via an RC element in such a way that the current assumes a higher value when switched on to initially activate the relay and then drops to the holding current.

The circuit may therefore comprise a voltage source configured to output a constant voltage to initiate the switching operation, and an arrangement of electrical components provided between the voltage source and the first input of the comparator, which derives the first voltage from the constant voltage and which causes the first voltage to drop to a level that causes the holding current after a certain period of time. In particular, the arrangement of electrical components may comprise an RC element.

The first input of the comparator may be connected to the voltage source through a voltage divider. The circuit may further comprise a switch which bridges a resistor of the voltage divider when the switch is closed. The circuit may further comprise a capacitor, wherein the voltage divider comprises a resistor connected in parallel with the capacitor.

A circuit according to the invention and a relay which comprises a relay coil may be comprised in a device.

A method according to the invention comprises generating a current flow through a relay coil to effect a switching operation by outputting a constant voltage from a voltage source and reducing the current flow through the relay coil to a holding current after the switching operation has been effected.

Furthermore, it is understood that all features described in connection with the circuit may also be features of the method and vice versa.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 is a schematic representation of a circuit according to the invention;

FIG. 1a shows a diagram illustrating a current flow through a relay coil, the current being controlled by the circuit shown in FIG. 1.

FIG. 2 shows a first embodiment of the circuit depicted in FIG. 1;

FIG. 3 shows a second embodiment of the circuit depicted in FIG. 1; and

FIG. 4 shows a flow chart of a method according to the invention.

### DETAILED DESCRIPTION

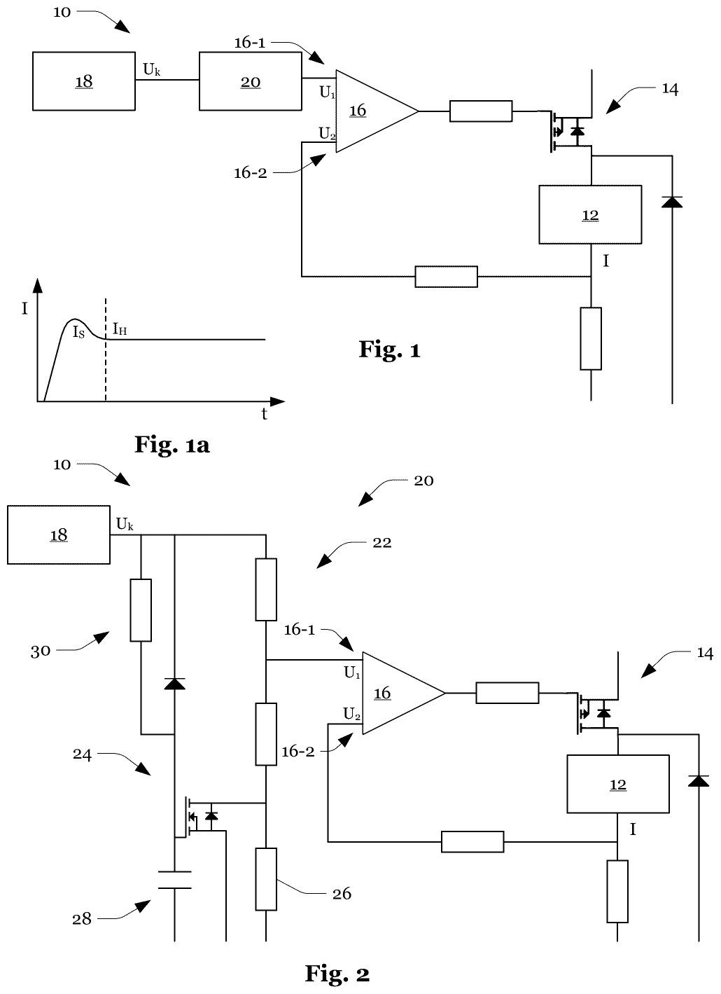

FIG. 1 shows a schematic illustration of a circuit 10 according to the invention. The circuit 10 comprises a relay coil 12 and an electronic switch 14 which controls the current flow I through the relay coil 12. The output voltage of a comparator 16 is applied to the control input of the electronic switch 14. To the first input 16-1 of the comparator, a reference voltage U₁ is applied which is derived from a (constant) output voltage Uₖ of a voltage source 18 (e.g. a linear regulator) by an arrangement 20 of electrical components. In addition to the reference voltage, the voltage source 18 may also provide the operating voltage for the switching regulator.

To the second input 16-2 of the Schmitt trigger comparator 16, a second voltage U₂ is applied which is derived from the current flow I through the electronic switch 14 and the relay coil 12. If the current flow I through the electronic switch 14 and the relay coil 12 decreases, voltage U₂ decreases. If voltage U₂ falls below voltage U₁, the output voltage of the comparator 16 is inverted and the electronic switch 14 becomes conductive, so that the current flow I increases again. If voltage U₂ becomes higher than voltage U₁, the electronic switch 14 is blocked and the current I drops again. This results in a triangular-shaped current I through the relay coil 12, the mean value of which is equal to the setpoint. As an alternative to the switching regulator, an integrated component may be used, e.g. a constant current driver for light-emitting diodes.

As illustrated in FIG. 1a, the arrangement 20 of electrical components ensures that when the voltage source 18 outputs the (constant) voltage Uₖ to initiate the switching process, the reference voltage U₁ is temporarily increased. This causes a (larger) switching current IS to initially flow through the relay coil 12, which is reduced to the holding current I_{H} after a certain period of time in which the switching process is completed (e.g. after a period of time after which the relay has picked up). By reducing the current I flowing through the relay coil 12 to the holding current IH, the energy consumption of the circuit 10 can be reduced.

FIG. 2 shows a possible embodiment of the circuit 10 shown in FIG. 1. Therein, the arrangement 20 of electrical components comprises a voltage divider 22, through which the first input 16-1 of the comparator 16 is connected to the voltage source 18. If the switch 24 is closed, the resistor 26 of the voltage divider 22 is bridged, by which the voltage U1 applied to the first input 16-1 of the comparator 16 decreases. The time at which the switch 24 is closed can be determined through the capacitor 28 and the resistor 30 such that the time period between the output of the voltage Uk and the closing of the switch 24 is long enough to complete the switching process.

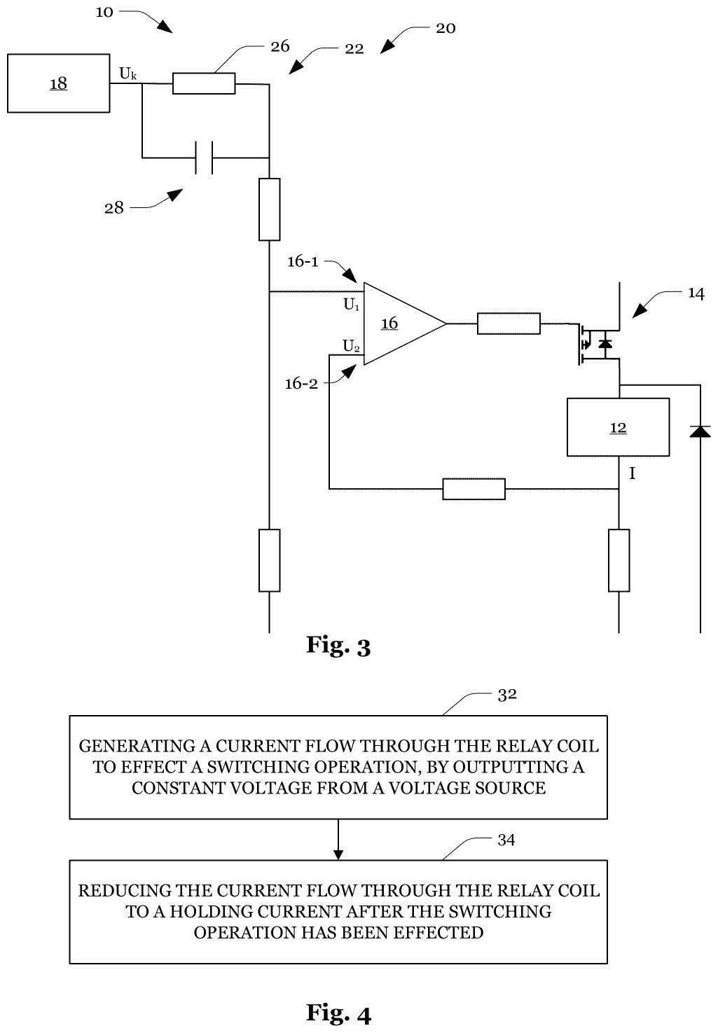

FIG. 3 shows a further possible embodiment of the circuit 10 shown in FIG. 1. Therein, the arrangement 20 of electrical components also comprises a voltage divider 22, through which the first input 16-1 of the comparator 16 is connected to the voltage source 18. However, the capacitor 28 is connected in parallel with a resistor 26 of the voltage divider 22, so that the voltage U₁ applied to the first input 16-1 of the comparator 16 decreases when the capacitor 28 is charged. The time at which or the speed at which the voltage U₁ decreases can be determined through the capacitor 28 and the resistor 26 so that the switching process can be completed before the current I through the relay coil 12 is reduced to the holding current I_{H}.

FIG. 4 shows a flowchart of a method according to the invention. It starts at step 32 with the generation of a current flow I through the relay coil 12 to effect a switching operation, by outputting a constant voltage Uₖ through the voltage source 18. At step 34, the method concludes with the reduction of the current flow I through the relay coil 12 to the holding current IH after the switching operation has been effected.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A circuit for controlling a current flow through a relay coil, the circuit comprising:
an electronic switch that controls the current flow through the relay coil; and
a comparator to control a control voltage applied to a control input of the electronic switch,
wherein a first voltage is applied to a first input of the comparator, and
wherein a second voltage derived from the current flow through the relay coil is applied to a second input of the comparator, and
wherein the circuit is configured to reduce the current flow through the relay coil to a holding current after a switching operation which is caused by a switching current through the relay coil.

2. The circuit according to claim 1, further comprising:
a voltage source configured to output a constant voltage to initiate the switching operation; and
an arrangement of electrical components provided between the voltage source and the first input of the comparator, the arrangement deriving the first voltage from the constant voltage and causing, after a certain period of time, the first voltage to drop to a level which results in the holding current.

3. The circuit according to claim 2, wherein the arrangement of electrical components comprises an RC element.

4. The circuit according to claim 1, wherein the first input of the comparator is connected to the voltage source through a voltage divider.

5. The circuit according to claim 4, further comprising:
a switch that bridges a resistor of the voltage divider when the switch is closed.

6. The circuit according to claim 4, further comprising:
a capacitor,
wherein the voltage divider comprises a resistor connected in parallel with the capacitor.

7. A device comprising a relay with a relay coil and the circuit according to claim 1.

8. A method for controlling a current flow through a relay coil, the method comprising:
generating a current flow through the relay coil to effect a switching operation by outputting a constant voltage from a voltage source; and
reducing the current flow through the relay coil to a holding current after the switching operation has been effected.
